(19) United States
(12) Patent Application Publication
(10) Pub. No.: US 2018/0137005 A1
(43) Pub. Date: May 17, 2018

(54) INCREASED REDUNDANCY IN MULTI-DEVICE MEMORY PACKAGE TO IMPROVE RELIABILITY

(71) Applicant: Intel Corporation, Santa Clara, CA (US)

(72) Inventors: Wei Wu, Portland, OR (US); Uksong Kang, Hillsboro, OR (US); Hussein Alameer, Portland, OR (US); Rajat Agarwal, Beaverton, OR (US); Kjersten E. Criss, Beaverton, OR (US); John B. Halbert, Beaverton, OR (US)

(21) Appl. No.: 15/814,336

(22) Filed: Nov. 15, 2017

Related U.S. Application Data
(60) Provisional application No. 62/422,576, filed on Nov. 15, 2016.

(51) Int. Cl. G06F 11/10; G11C 29/52

(52) U.S. Cl. CPC G06F 11/1068; G11C 29/52

(57) ABSTRACT

In a memory system a multichip memory provides data redundancy for error recovery. The multichip memory can be an integrated circuit package with multiple memory dies or memory devices integrated with a common package. The multiple memory dies are coupled in a daisy chain, and can be a vertical stack or in a planar formation. The memory chip or chips at the end of the chain store parity data, and the other devices store data. The multichip memory includes XOR (exclusive OR) logic to compute parity to store in the redundant parity chips.

### PRIORITY

The present application is a nonprovisional application based on U.S. Provisional Patent Application No. 62/422,576, filed Nov. 15, 2016. The present application claims the benefit of priority of the provisional application.

### FIELD

Descriptions are generally related to memory subsystems, and more particular descriptions are related to memory reliability, accessibility, and serviceability.

### BACKGROUND

The increased demand for memory resources has led to the development of memory devices with multiple memory dies or devices in a single package. The single package is typically a high bandwidth device or wide interface device or both, such as high bandwidth memory (HBM) or wide input/output interface (WideIO) memory, which are typically implemented as a three-dimensional stack of memory dies within a package that has a high-bandwidth I/O (input/output) connection. The dies may be connected to a logic die of the multi-device memory package by way of vertical interconnects such as through-hole connections (e.g., through-silicon vias or TSVs). Multi-device memory packages result in a much higher density memory solution compared to traditional memory dies coupled together on a board (such as in a dual inline memory module or DIMM). The high-density, high-bandwidth devices suffer from errors as do traditional memory devices. However, with such high density inside a single package, the reliability issues are increased.

Conventional memory implementation in DIMMs deal with reliability by resource redundancy, such as adding one or more spare memory devices on a DIMM. Thus, no memory device stores an entire cacheline or wordline, but the data is spread among devices in the DIMM. With such a configuration, failure of an entire memory device can still be corrected through ECC (error correcting code or error checking and correction). However, with a multi-device memory package, a memory device typically stores an entire cacheline or wordline in a single bank or chip. The conventional redundancy routines cannot recover data in the multi-device memory.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a memory subsystem with a multi-device memory that includes redundancy.

FIG. 2A is a block diagram of an example of a data mapping for a multi-device memory stack with redundancy.

FIG. 2B is a block diagram of an example of a multi-device memory stack illustrating data mapping and a sequence of operations for a write.

FIG. 2C is a block diagram of an example of a multi-device memory stack with XOR logic at each block illustrating a sequence of operations for a write.

FIG. 2D is a block diagram of an example of data mappings for a vertically stacked multi-device memory.

FIG. 3A is a block diagram of an example of a multi-device memory stack with mirroring.

FIG. 3B is a block diagram of an example of a multi-device memory stack with a parity block.

FIG. 4A is a block diagram of an example of shifted signal passthrough in a multi-device memory stack.

FIG. 4B is a block diagram of an example of loop structure to connect passthrough receivers of a multi-device memory together.

FIG. 5 is a flow diagram of an example of a process for reading data in a multi-device memory implemented with redundancy.

FIG. 6 is a flow diagram of an example of a process for writing data in a multi-device memory implemented with redundancy.

FIG. 7 is a block diagram of an example of a memory subsystem with a multi-device memory with redundancy logic.

FIG. 8 is a block diagram of an example of a computing system in which a multi-device memory with redundancy logic can be implemented.

FIG. 9 is a block diagram of an example of a mobile device in which a multi-device memory with redundancy logic can be implemented.

Descriptions of certain details and implementations follow, including non-limiting descriptions of the figures, which may depict some or all examples, and well as other potential implementations.

### DETAILED DESCRIPTION

As described herein, reliability of a multi-device memory can be improved with increased redundancy at higher levels than typical ECC (error correcting code, or alternatively, error checking and correction) redundancy. A multi-device memory can refer to a high bandwidth memory (HBM) or wide input/output interface (Wide IO (WIO)) memory device or other memory package that includes multiple separate memory devices (e.g., memory chips or memory dies) connected together in a single memory device package. The memory device package can include a vertical stack or can include a planar configuration of the memory devices. In one example, the vertical stack or planar configuration of devices includes a daisy chain of devices, with each device connected in turn. The example herein are not limited to daisy-chaining of devices even when such an example may be specified. The devices include a device that is furthest physically from a connection point along a data path or signal path. The physically furthest device or devices will be present whether the devices are all directly connected to a common logic die, or whether the devices are daisy-chained. In one example, the device or devices farthest along the path or farthest from the memory controller are parity devices or devices that store parity information.

The increased, higher levels of redundancy implemented in memory subsystems with such devices can provide error recovery in situations where conventional approaches would result in an unrecoverable error. In contrast to conventional memory devices (e.g., commodity dynamic random access memory (DRAM) devices), multi-device memories store an entire cacheline or wordline in a single bank or chip. The following descriptions generally make reference to HBM memory devices, and will be understood to apply to other memory packages that include multiple memory devices in-package that are externally accessed as a single device. Reference to HBM will thus be understood to be a non-limiting example. Additionally, examples illustrate vertical stacks, but will be understood to apply to either vertical stacks or planar configurations.

In a conventional DRAM memory module, one cacheline is distributed into multiple independent devices. So if one of the devices fails, only part of the information is lost, and thus, even when one chip fails, a redundant ECC chip can help to recover the data. However, in HBM, one cacheline is stored in same bank or chip. Error recovery cannot be performed at the level of blocks of the cacheline. As described herein, one or more layers of higher-level redundancy can achieve similar data protection and data recovery for HBM as currently implemented for DRAM DIMMs. Conventional DRAM failure typically results in the loss of only part of the cacheline. The conventional solution of protecting against the failure of one device is to have two extra devices to store ECC bits, and employ symbol-based correction to recover the data.

In one example, the internal portions of an HBM device can be ordered similarly to a redundant array of independent disk (RAID) system or a redundant array of independent memory (RAIM). In one example, modifications to the HBM device and the memory subsystem, as compared to traditional approaches to HBM, can enable management of HBM devices in a manner similar to a RAID implementation. Such an implementation can protect a row, or bank, or device failure. In implementations where an HBM device is integrated onto a processor in a single package, conventional errors could destroy the functionality of not only the multi-device memory, but the processor as well. However, with higher level redundancy that enables error recovery, the risk of loss of such a combined package is reduced.

In a memory system a multichip memory provides data redundancy for error recovery. The multichip memory can be an integrated circuit package with multiple memory dies or memory devices integrated with a common package. The multiple memory dies can be a vertical stack or in a planar formation. The memory chip or chips at the end of the chain store parity data, and the other devices store data. The multichip memory includes XOR (exclusive OR) logic to compute parity to store in the redundant parity chips.

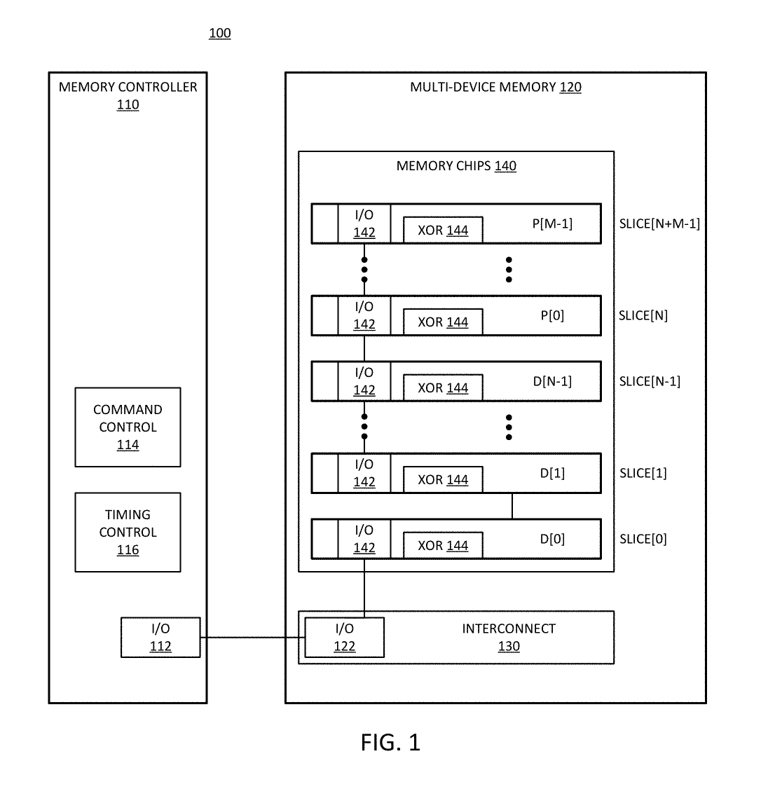

FIG. 1 is a block diagram of an example of a memory subsystem with a multi-device memory that includes redundancy. System 100 provides an example of memory controller 110 coupled to multi-device memory 120. Memory controller 110 represents a device or circuit to control access to the memory resources of memory 120. Memory 120 represents memory resources coupled to memory controller 110 on a memory bus of system 100. Memory 120 can be or be included as main memory for execution of instructions by a host processor (not shown).

Memory controller 110 includes I/O 112, which represents hardware elements to couple to memory 120. Memory 120 similarly includes I/O 122, which represents hardware elements or circuitry to connect to memory controller 110. I/O 112 and I/O 122 can be connected by one or more buses, such as a command bus and a data bus.

Memory controller 110 includes command control 114, which represents logic within memory controller 110 to generate access and control commands to send to memory 120. Examples of access commands can include read or write commands. For purposes of system 100, read and write commands can be controlled with respect to redundancy implemented by memory 120 to increase RAS (reliability, accessibility, and serviceability).

Timing control 116 represents the control of memory controller 110 over the timing of the sending of commands. The timing control can be referred to as scheduling, with memory controller 110 controlling the timing of access commands based on availability of memory 120. Various techniques are known to send commands to different channels, different banks, different ranks, or some combination, to increase the bandwidth utilization of the data bus to enable higher throughput. Such techniques will not be described in detail here. For purposes of system 100, timing control 116 can control the timing of commands based on timing consistent with the operation of memory 120 to provide redundancy.

For example, consider that as part of the operation of redundancy of memory 120, various write commands result in write transactions that include additional operations within memory 120, which increases the time to execute a write transaction relative to traditional write commands. More specifically, consider that a standard write command results in a read-modify-write within memory 120, which takes longer than a standard write operation. Memory controller 110 controls the scheduling of commands based on settings or configuration to indicate that memory 120 performs redundancy and will take longer to write. In another example, consider that as part of the redundancy of write, every write transaction results in multiple sub-operations. As part of such a configuration, memory controller 110 can generate multiple sub-commands with command control 114 and adjust the sending of commands with timing control 116 to ensure that the multiple sub-commands are sent and received for proper execution.

In one example, redundancy may result in read delays relative to standard reads based on the computation of error checking or parity checking or the potential need to reconstruct data from the redundancy. In one example, all reads are delayed to allow for the possibility of data reconstruction. In one example, there is one timing for data without errors, and another read delay for data that needs reconstruction. Such operation can be triggered by memory 120 with a signal sent from the memory. Based on the configuration of the system, memory controller 110 adjusts the reading of data to satisfy read requests based on timing adjustments for redundancy.

Memory 120 can include memory chips 140, which can alternatively be referred to as memory dies. In one example, memory 120 includes interconnect 130 to connect to memory chips 140. In one example, I/O 122 for memory 120 is included in interconnect 130, or interconnect 130 couples to I/O 122.

Memory chips 140 can include [N+M−1] memory slices. A slice refers to a chip or die integrated onto a substrate. Interconnect 130 can be the substrate for a vertical stack. Alternatively, a substrate can include a planar layout of memory devices, or a combination of a planar layout of multiple stacks of memory chips. In one example, any such configuration can be integrated onto an SOC (system-on-a-chip) or processor.

The various memory slices are illustrated to include I/O 142, which represents interconnections among the various memory chips 140 with each other and with interconnect 130, which can be or include a logic die or substrate or master device. In one example, every memory slice includes XOR logic 144. XOR logic 144 represents logic within memory 120 to perform redundancy operations, such as perform XOR operations to write parity.

As illustrated, memory chips 140 can include N+M memory slices, Slice[0:N+M−1]. Of the memory slices can be N memory slices, Slice[0:N−1] as data stacks D[0:N−1]. Additionally, memory chips 140 can include M parity slices, Slice[N:N+M−1] as parity stacks P[0:M−1]. Typically N is greater than M. M is at least 1, and N is typically at least 3. The configuration of memory chips 140 can provide improvements over other stacked memory systems or redundant memory arrays, in that with parity at the “top” of the stack or “end” of the chain from the logic chip, the computation and writing of parity can be simplified relative to traditional systems. A parity stack at the top or end refers to being farthest physically from the memory controller, which means that it is towards the end of the data path of a multidrop or bus with a fly-by topology. In one example, having local XOR logic at each slice and the parity at the end can reduce the overhead associated with computing and writing the parity information.

In one example, in response to a write command received from memory controller 110, memory 120 writes the data on the data bus, as well as writing parity data. Thus, one or more of the data stacks will write the data, and parity is stored in one of the parity stacks. In one example, memory 120 executes write operations include writing parity in response to separate write and write parity sub-commands from memory controller 110. For example, memory controller 110 may issue two separate write commands for each command, to trigger memory 120 to write the data as well as the parity. In another example, memory controller 110 sends a single write command, and memory 120 executes both data write and parity write operations in response to the command.

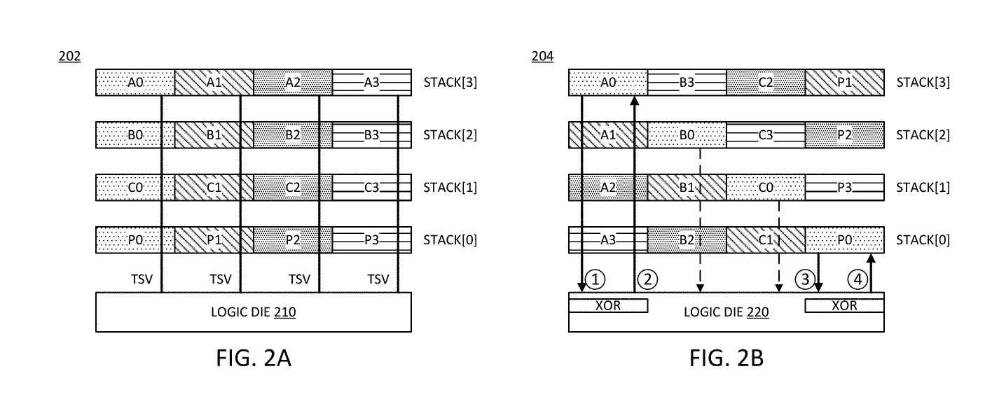

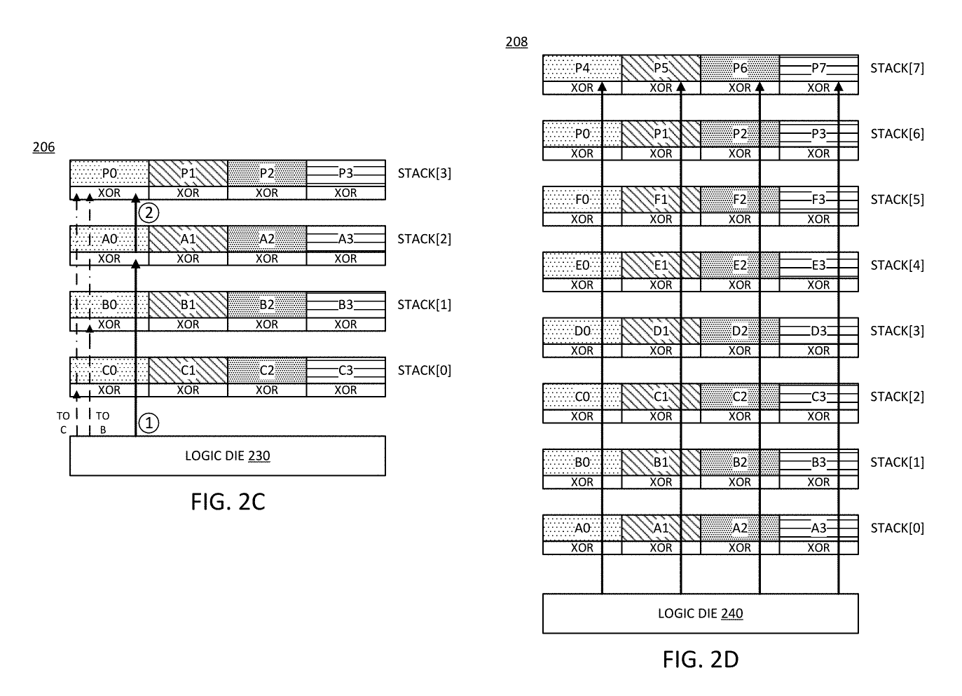

FIG. 2A is a block diagram of an example of a data mapping for a multi-device memory stack with redundancy. Diagram 202 represents a data mapping possible within an HBM device. In one example, diagram 202 represents a 4-high stack of memory dies. The stacks or individual memory device dies can couple to logic die 210 through TSVs.

In one example, data and parity that belong to same logical unit are distributed into independent physical locations. In one example, the mapping or organization of the distribution of the data in controlled by a controller of the memory device, such as implemented in a logic die or a memory controller or a combination. In one example, a memory controller of the host can map cachelines into different regions, such as banks or channels. Diagram 202 illustrates each logical unit of four cachelines residing in the same vertical column. One example of diagram 202 represents a mapping for 16 banks with 4 logical units. In one example, the same 16 banks can be mapped as two groups of 8 banks. Different channel and bank configurations are possible.

In one example, if data is mapped to a different channel, the memory controller can support inter-controller communication, such as between different ones of multiple memory controllers in the system. In one example, inter-controller communication can include lockstep channels, where a data write to one channel can trigger a parity change in another channel. In one example, the data or command or address information, or a combination, is passed along an inter-controller bus connecting the multiple memory controllers.

The example of diagram 202 provides one parity (or ECC) block and the rest data blocks. Thus, Stack[0] can represent a parity block or parity die, and Stack[3:1] can represent data blocks or data dies. A similar configuration could exist with an 8-high stack, with one parity block and 7 data blocks, which will be understood to provide weaker data protection than one parity block per 4 block logical unit. For the sake of simplicity, multiple descriptions below assume an HBM configuration with 3 data blocks and 1 parity block. Other configurations of HBM and other memory packages will be understood.

FIG. 2B is a block diagram of an example of a multi-device memory stack illustrating data mapping and a sequence of operations for a write. Diagram 204 represents a data mapping possible within an HBM device. Diagram 204 illustrates logical units distributed through the stack, as opposed to being within the same vertical column as in diagram 202. The mapping of diagram 204 can be considered a more distributed and rotated mapping topology relative to that of diagram 202. In one example, Stacks[3:0] are coupled to logic die 220 with TSV connections.

One example of diagram 202 represents a mapping for 16 banks with 4 logical units. In one example, the same 16 banks can be mapped as two groups of 8 banks. Different channel and bank configurations are possible. The example of diagram 204 provides one parity (or ECC) distributed throughout the blocks, with an equivalent of one parity block and the rest data blocks. A similar configuration could exist with an 8-high stack, with parity and data distributed throughout.

Diagram 202 illustrates a write process in an HBM with distributed data blocks. In one example, all parity data is in a single column. In one example, parity is in a single stack. In one example, every write in such an implementation requires four operations. Consider an example of writing to A1. The difference between the new data A1 and old data A1 can be referred to as delta (Δ) for the following examples. The first operation is to Read the old A1 data. The second operation is to Write the new A1 data to A1. The third operation is to Read the old P1. In one example, logic die 220 computes the new P1 as P_new=A1_old XOR A1_new XOR P1_old (bit by bit or bitwise XOR), where the XOR operation can also be indicated by the operator ‘̂’. The fourth operation is to Write P_new to P1.

FIG. 2C is a block diagram of an example of a multi-device memory stack with XOR logic at each block illustrating a sequence of operations for a write. Diagram 206 illustrates an example of a multi-device memory with multiple memory blocks in accordance with an example of system 100. In one example of diagram 206, every data block includes XOR logic, instead of XOR logic only residing in logic die 230. In one example, each DRAM bank is XOR-enabled. As provided in diagram 206, the four operations for write as set out in diagram 204 become only two operations, because the data does not need to be transferred additional times to execute the XOR operations. In one implementation, the stacks include XOR logic, while there is not necessarily XOR logic at every block or at every DRAM bank.

In one example, instead of providing a parity layer on the layer closest to logic die 230, the parity layer (P[0:3]) can be at the top of the 3D stack or at the end of a daisy chain of devices. In one example, the devices are daisy chained together. In one example, each data stack has a dedicated connection (e.g., a TSV connection) to the parity stack (Stack[3] as illustrated). In one example, all stacks include a dedicated connection (e.g., TSV) to logic die 230. In the example of diagram 206 or other examples, the TSV connections could alternatively be optical fiber connections or VCSEL (vertical cavity surface emitting laser) connection, or other connection, or a combination.

With the parity blocks at the “end”, and XOR calculations performed within each layer, the number of operations can be reduced by simply continuing to pass the data on, but passing on modified data. In one example, the memory banks perform XOR calculations internally to the DRAM core die during writes. Having the memory stacks perform the XOR operations can reduce the read/write TSV power by up to 4× for all writes by reducing the number of round trips for data.

In accordance with an example of diagram 206, the same write to A1 would include Write operations that are, or are similar to a Read-Modify-Write (RMW). Thus, the write operation can include two operations. First, send A1_new to Stack[2], which can Read A1_old, and compute Δ=A1_old XOR A1_new, and Write A1_new to A1. Second, Stack[2] can send A to Stack[3], which can Read P1_old and compute P1_new=Δ XOR P1_old. Stack[3] could then write P1_new to P1.

In one example, a Read operation from A1 includes a Read operation in accordance with a traditional read, with data correction based on the redundancy only performed when an uncorrectable error is detected.

In one example, one or more of the redundancy-based configurations of a multi-device memory will require a change to a memory subsystem in accordance with one or more of the following. In one example, each DRAM block includes its own local XOR logic. In one example, each Write (WR) access to stacks other than the parity stack are RMW operations. In one example, the memory controller supports the RMW version of write associated with the “WR-and-Update” operations. As such, a new command can be issued, or a write command can be treated as a WR-and-Update command.

In one example, such a command can be implemented in accordance with two sub-commands, one subcommand for the first Write to A1, and a second subcommand for the parity write. In the illustration of diagram 206, operation 1 represents the write of the data to the memory stack, and operation 2 represents the write of the parity data to the parity stack. Either or both writes can include RMW operations. In one example, the memory controller determines the timing between the two subcommands by the read-modify-write latency for the memory devices. In one example, such a command can be implemented as a master command from the memory controller, which the internal controller of the memory device decodes, and each die in the stack can initiate the write and trigger the parity write automatically in response to the write operation.

In the example of diagram 206, the data organized into one logical unit (A1, B1, C1 and P1) is allocated within one vertical column. The arrows that start at the logic die show the conventional TSV pathway to perform the write operation to the desired block. The arrows that start at the top of those arrows show a modified TSV pathway. In one example, diagram 206 includes a modified TSV, where the delta value between the old and new data will be passed to the parity information block (e.g., the top of the stack). In one example, a modified TSV includes a change at each stack level, to have more receiver/transceivers enabled. For example, the top stack (parity level) may need to have four receivers (one from logic die TSV connections, and three from data TSV from other stacks). In one example, a modified TSV includes a change in the delay of write operations, which delay will increase to perform the dual operations described above.

In one example, a system implementing redundancy in an HBM can manage simultaneous access to reduce conflicts. Consider that if three dies share a parity die, simultaneous access to different data dies could result in multiple deltas trying to access the parity die at the same time. In one example, such delta collisions can be controlled by memory controller implementing an access restriction. As such, simultaneous access is not permitted to happen, and at any cycle, no more than one data block within a RAID logical unit is being written. For example, the memory controller can be configured with address information for the different dies, and include a scheduling rule that implements an address restriction to prevent conflicts. In such an implementation, the parity delta would only need a single buffer to store one delta.

In one example, the system can permit simultaneous access, and implement collision avoidance at the DRAM dies. In one example, the DRAM dies can include multiple buffers. In one example, each DRAM can include a buffer as deep as the stack is high, or as deep minus one), to buffer more data elements. In one example, the DRAM devices will also include more XOR logic and potentially other logic to route signals. In one example, the parity level bank needs to have multiple buffers instead of one, where each buffer holds the delta value from one stack. In one example, each die includes multiple separate XOR circuits to calculate: P_new=P_old̂ΔÂΔB̂ΔC.

In one example, error propagation to parity can occur during a RMW operation. Error propagation refers to one of the data having an undetectable error (e.g., miscorrected by internal ECC), which error will then be carried on when a new write overwrites the old value, and the delta which carries the error information is written into the parity block. As the parity is contaminated, it is not possible to correct any device failure, because the calculations meant to correct the data will not be reliable.

In one example, error propagation can be managed by frequent data scrubbing. By reading and checking the validity of data constantly, the system can hopefully identify and correct the errors. Such scrubbing may be performed by external ECC, which has better coverage than internal ECC, and is certainly better coverage than no internal ECC. The scrubbing provides a refresh of the value of the data. Traditionally, scrubbing is performed one device die at a time. In one example, a system in accordance with any example herein that supports group scrubbing. Group scrubbing can refer to group verification of data, for example, by checking the consistency between all values within a logical unit. Group scrubbing may require the reading out of all dies in the stack (e.g., A/B/C/P in diagram 206), and performing a parity check.

FIG. 2D is a block diagram of an example of data mappings for a vertically stacked multi-device memory. Diagram 208 represents an example of a multi-device memory in accordance with an example of system 100. Whereas diagram 206 of FIG. 2C represents an example implementation with a 4-device stack, diagram 208 represents an 8-high stack in accordance with any example herein that supports are can be modified to support 8 dies.

It will also be understood that the labels of the data can be a convention, and is not to be understood restrictively. For example, in diagram 206, Stack[2], which is adjacent Stack[3] that stores parity data, is illustrated to store data A. Furthermore, Stack[1] is illustrated as storing data B, and Stack[0] is illustrated to store data C, with Stack[0] closest to logic die 230. In diagram 208, Stack[0] closest to logic die 240 is illustrated as storing data A, with Stacks[1:5] storing, respectively, data B, data C, data D, data E, and data F. Stack[6] is illustrated as storing parity blocks P[0:3], and Stack[7] is illustrated as storing parity blocks P[4:7]. The order of data A:F could be reversed with respect to Stacks[0:5].

While an example of diagram 208 illustrates six data stacks and two parity stacks, other configurations are possible. For example, there could be seven data stacks in Stacks[0:6] with one parity stack in Stack[7]. In another example, there could be five data stacks in Stacks[0:4] and three parity stacks in Stacks[5:7].

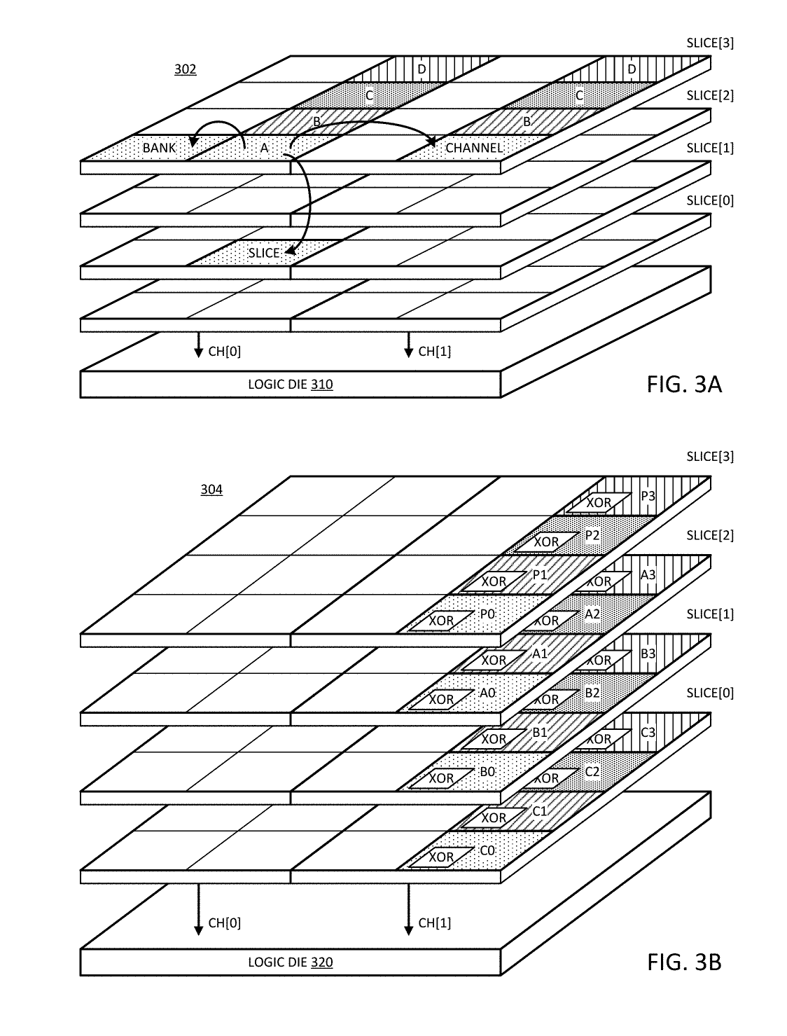

FIG. 3A is a block diagram of an example of a multi-device memory stack with mirroring. System 302 provides one example of a 4-high HBM memory stack, with Slices[0:3]. Stacks and slices refer to an integrated memory device coupled in sequence along a connection with other memory device I/Cs (integrated circuits). In one example, each of the four stacks has 16 banks, which are divided into two channels (Channel 0 (CH[0]) and Channel 1 (CH[1])). While the mapping of banks can be any configuration, as shown, the banks to one side belong to Channel 0, and the banks to the other side belong to Channel 1. An example of system 302 includes logic die 310 underneath the memory dies to provide logic for the HBM. While a stack of four is illustrated, it will be understood that system 302 can include a stack of eight, or some other stack. In one example, system 302 can include multiple stacks, each with 2, 4, 8, or some other number of dies. In one example, the number of channels is different than two. In one example, the number of banks is different than 16 per die.

In one example, the banks of system 302 can be organized as logical units for purposes of data reliability. Similar to RAID, in one example, the multiple banks can be organized as RAID organizes multiple physical disk drives into a single logical unit.

Mirroring is one of the simplest forms of redundancy to implement, and includes mirroring or making a copy of every piece of data. The mirroring can happen at different levels. As illustrated in system 302, mirroring can be between two rows inside a bank, between two banks, between two stacks or slices, or between two channels. The highlighted blocks pointed to by the arrows represent different options for mirroring.

In one example, the memory controller (not specifically illustrated) will control the mirroring. Thus, a memory controller can direct the same data to be written to multiple locations. In one example, the internal controller of the memory device (e.g., a controller implemented on the logic die) controls the mirroring. In such a scenario, the device only exposes half its capacity to the host, and for every write operation, the internal logic generates operations to write the same data to two locations.

It will be understood that mirroring or any other form of redundancy is used for error recovery when an error is detected. Thus, system 302 and other example assume a mechanism to detect uncorrectable errors to determine when to perform error recovery based on redundancy. In one example, the error detection mechanism includes internal ECC logic. In one example, the error detection mechanism includes external ECC logic. In one example, the error detection mechanism includes internal and external ECC logic. It will be understood that internal ECC logic refers to logic within the memory device itself, and external ECC logic refers to logic external to the memory device. The external ECC logic can include logic in a memory controller or in another location of the memory subsystem, such as a board or substrate through which the memory device connects to the host, or in logic die 310.

In one example, detection or identification of an uncorrectable error triggers a correction based on redundant data in the memory device. In one example, the error detection includes identifying a bank or row or column or other segment with an error. In one example, an error can be detected by external ECC logic, such as an ECC check showing an uncorrectable error. In one example, error detection can include an indicator, such as an alert signal that detects command/address bus errors. In one example, error detection can include any mechanism (e.g., a BIST) used to detect a die failure. It will be understood that the error detection and redundancy correction can be orthogonal to DRAM on-die internal ECC. Thus, individual DRAM dies within the multi-device memory can include and implement internal ECC separately from the redundancy described herein. In one example, internal ECC can provide information that may help with error detection. Not all internal ECC implementations will provide information sufficient to help with error detection.

FIG. 3B is a block diagram of an example of a multi-device memory stack with a parity block. System 304 provides one example of a system in accordance with system 206 or with system 100. In one example, system 304 includes a stack of four dies or four slices, Slices[0:3]. In one example, Slice[2] can store data A, Slice[1] can store data B, Slice[0] can store data C, and Slice[3] can store data P. Data A, B, and C refer to user data, while data P refers to parity information computed within the memory device itself. Thus, system 304 provides an example of a memory system having a configuration similar to RAID with 3 data disks (A, B, C)+1 parity disk (P). Without the loss of generality, system 304 illustrates 4 banks along the side from each stack, A0, B0, C0, and P0, while other mapping configurations can be used.

In one example, the value of the parity information is an XOR of all the segments of data. Thus, the value of P0 can be stated as: P0=A0̂B0̂C0 where parity bits are calculated by XORing all corresponding data bits. Assume for one example a data granularity of one cacheline. Different granularity is possible, such as multiple cachelines, or portions of cachelines. In one example, a logical unit of data for system 304 includes four cachelines, A0, B0, C0 and P0, where each line is stored in a separate bank as the single block. In one example, P0 is the parity of all data blocks. When one bank fails, system 304 can enable the reconstruction of the information from rest of the lines in the same logical unit. For example, consider that A0 fails. A0 can be reconstructed as follows: A0=P0̂B0̂C0.

System 304 illustrates XOR logic at each block, such as on Slice[0] at A[0:3], on Slice[1] at B[0:3], and so forth. While the TSV or other inter-stack connections are not specifically illustrated, it will be understood that the stacks are coupled by physical paths that allow the computation of XOR operations and passed along to subsequent stacks.

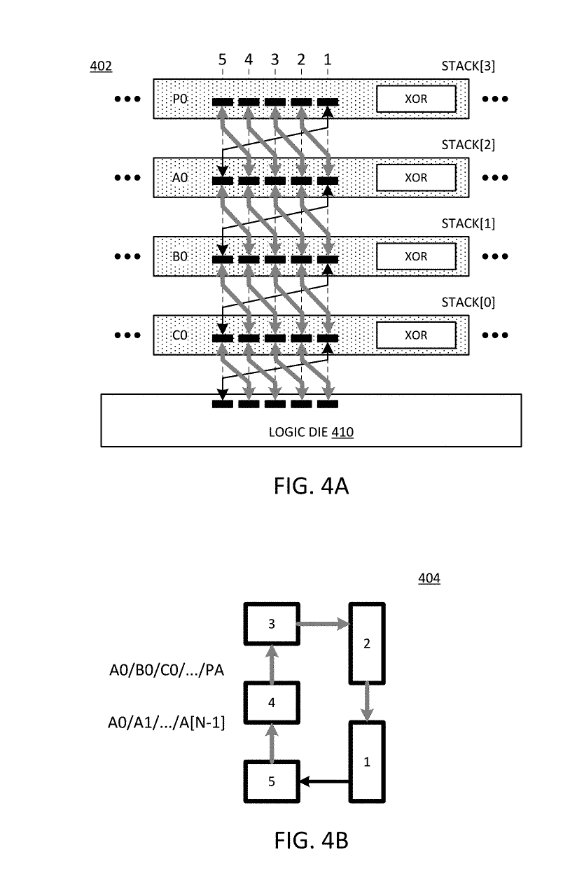

FIG. 4A is a block diagram of an example of shifted signal passthrough in a multi-device memory stack. Diagram 402 provides an example of a stack layout in which delta information is sent to the top stack with a modified TSV structure. Diagram 402 can be implemented in any example of a multi-device memory with redundancy herein, such as in system 100. Instead of having 4 receivers as with a traditional system, in one example, each stack includes 5 receivers, and each receiver is connected to the lower stack in a shifted style. Thus, for example, the 5th (left-most) is connected to 4th, and 4th is connected to 3rd, and so forth. The 1st is connected to the 5th. The connection can continue with such a configuration from logic die 410 all the way to the last stack. For simplicity, only a single block of the stack is illustrated: blocks C[0] for Stack[0], B[0] for Stack[1], A[0] for Stack[2], and P[0] for Stack[3].

With such a relay of signals, the configuration can provide a compact structure that would allow 1× write TSV power while with the conventional TSVs, 2× write TSV power would be used. Even with the conventional implementation, the power operation is improved over the traditional case, which requires a relative 4× power, when all XOR operations are performed in the logic die. It will be understood that there is a tradeoff between power and chip size. The space sharing of diagram 402 can provide lower power, but with increased size relative to having all logic in logic die 410. In one example, each logic block for each stack includes XOR logic that can couple to the TSV structure.

FIG. 4B is a block diagram of an example of loop structure to connect passthrough receivers of a multi-device memory together. Diagram 404 illustrates a loop structure to connect the five receivers of diagram 402 together. Diagram 402 provides a representation of the connections from a cross-section view of the stacks, diagram 404 provides a representation from a “top view” looking down onto a stack. The architecture of diagram 404 can be applied to the configuration of diagram 402 or to another configuration. In one example, the configuration illustrated can apply to all slices, such as A0, B0, C0, and Parity (PA). In one example, the configuration can apply to the logic die. In one example, the configuration can apply to all banks of a slice, such as A0, A1, . . . , A[N−1], where N represents the number of banks or logic blocks within a slice.

As an example of the configuration of diagram 404, consider the delta of A0 is calculated in receiver 5. The delta can be moved to receiver 4, to be sent to the level of P0. Alternatively, the delta can be moved from receiver 5 to receiver 1 to be sent to the level of P0, depending on the configuration of the receivers. The ring structure or loop structure can be controlled by logic to determine which transceiver to use to send data up or down the stack. In one example, each “bit TSV” includes 256 bits.

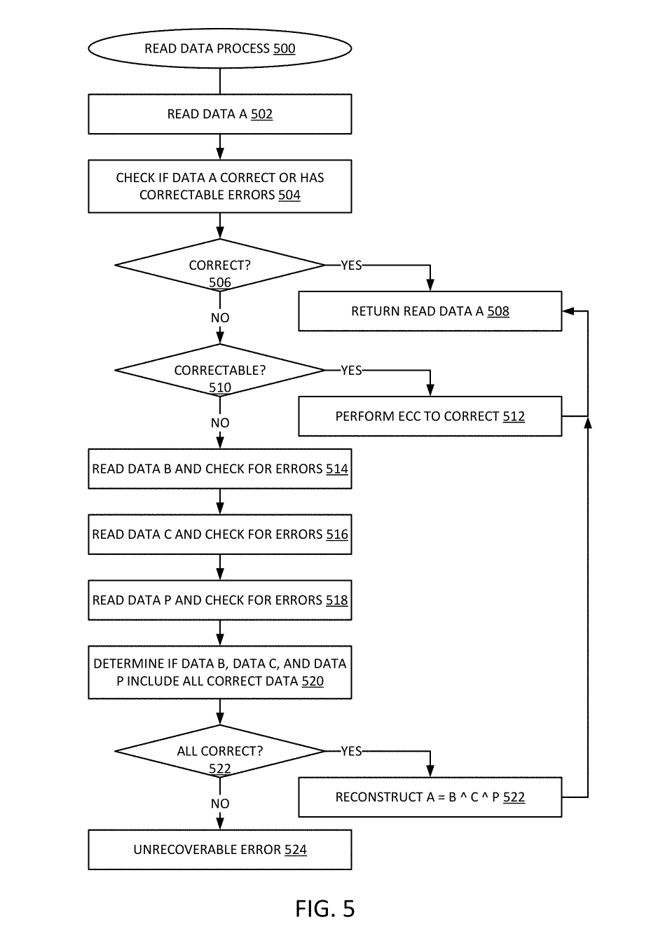

FIG. 5 is a flow diagram of an example of a process for reading data in a multi-device memory implemented with redundancy. Process 500 can be executed by an example of system 100. In one example for process 500 for reading data, a memory controller issues a read for Data A to an HBM with redundancy, 502. In one example, an error detection mechanism (either external or internal or both) checks to determine if Data A is correct, or if it contains correctable errors, 504. If the data is correct, 506 YES branch, the memory returns Data A, 508. If the data is not correct, 506 NO branch, but the errors are correctable, 510 YES branch, in one example, an error correction mechanism corrects the errors, and the operations continue, 512. The memory can then return the corrected read Data A, 508.

In one example, if there is an uncorrectable error, 510 NO branch, the memory perform data reconstruction based on the redundancy. In one example, the memory reads Data B and checks it for errors, 514, reads Data C and checks it for errors, 516, and read Data P and checks it for errors, 518. In one example, the correction logic determines if all of Data B, Data C, and Data P are clean data or include all correct data, 520. In one example, the data can be intrinsically clean as having no errors in it, or the data can be corrected to have no errors. If the data is all correct, 522 YES branch, the system reconstructs A from Δ=B̂ĈP, 522, and can then return read Data A, 508. If any of the other data includes an error and A cannot be recovered, then there is an unrecoverable error, 524.

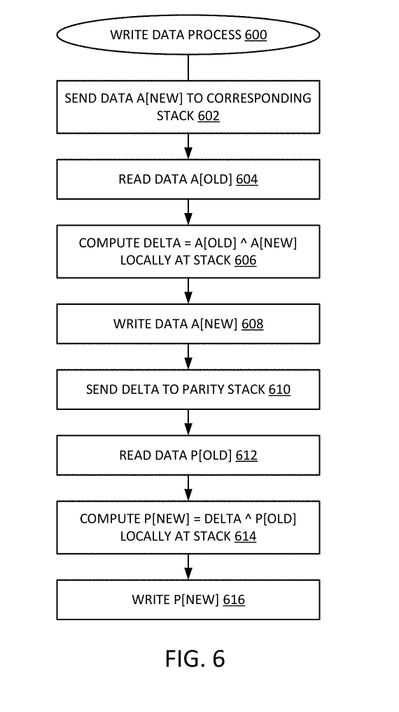

FIG. 6 is a flow diagram of an example of a process for writing data in a multi-device memory implemented with redundancy. Process 600 can be implemented by any example of a multi-device memory with redundancy herein, such as system 100, or memory 304. In one example of write process 600, a memory controller sends Data A[new] to a stack corresponding to an address of a write command, 602. In one example, the memory reads Data A[old], 604, and computes Delta=A[old] XOR A[new] locally at the memory stack, 606. Locally at the stack refers to not having to send the data down to the logic die for computation of the XOR operation(s).

In one example, the memory stack then writes Data A[new], 608, and sends the computed Delta to a parity stack, 610. In one example, the parity stack is located farthest from the associated memory controller along a path of the command. In one example, the parity stack is located farthest from the associated memory controller along a path of the data. At the parity stack, in one example, the memory reads Data P[old], 612, and computes P[new]=Delta XOR P[old] locally at the parity stack, 614. The parity stack then writes P[new], 616.

The memory performs both the write operation of the data as well as the write operation of the parity in response to a memory controller write operation. In one example, the write operation includes a single command, and the memory automatically performs both write operations. In one example, the memory controller sends multiple separate sub-commands to execute the data write and the parity write.

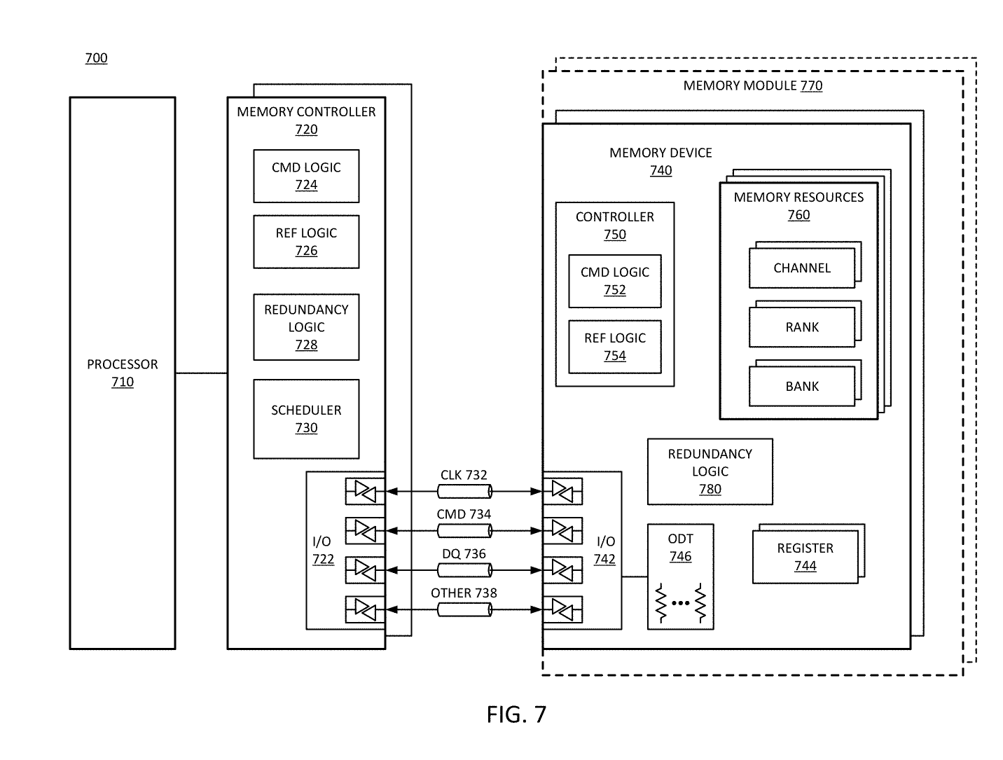

FIG. 7 is a block diagram of an example of a memory subsystem with a multi-device memory with redundancy logic. System 700 includes a processor and elements of a memory subsystem in a computing device. Processor 710 represents a processing unit of a computing platform that may execute an operating system (OS) and applications, which can collectively be referred to as the host or the user of the memory. The OS and applications execute operations that result in memory accesses. Processor 710 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 700 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random access memory), or some variant such as synchronous DRAM (SDRAM). A memory subsystem as described herein may be compatible with a number of memory technologies, such as DDR4 (DDR version 4, JESD79, initial specification published in September 2012 by JEDEC), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235A, originally published by JEDEC in November 2015), DDR5 (DDR version 5, currently in discussion by JEDEC), LPDDR5 (currently in discussion by JEDEC), HBM2 ((HBM version 2), currently in discussion by JEDEC), or others or combinations of memory technologies, and technologies based on derivatives or extensions of such specifications.

In addition to, or alternatively to, volatile memory, in one example, reference to memory devices can refer to a nonvolatile memory device whose state is determinate even if power is interrupted to the device. In one example, the nonvolatile memory device is a block addressable memory device, such as NAND or NOR technologies. Thus, a memory device can also include a future generation nonvolatile devices, such as a three dimensional crosspoint memory device, other byte addressable nonvolatile memory devices, or memory devices that use chalcogenide phase change material (e.g., chalcogenide glass). In one example, the memory device can be or include multi-threshold level NAND flash memory, NOR flash memory, single or multi-level phase change memory (PCM) or phase change memory with a switch (PCMS), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory.

Descriptions herein referring to a “RAM” or “RAM device” can apply to any memory device that allows random access, whether volatile or nonvolatile. Descriptions referring to a “DRAM” or a “DRAM device” can refer to a volatile random access memory device. The memory device or DRAM can refer to the die itself, to a packaged memory product that includes one or more dies, or both. In one example, a system with volatile memory that needs to be refreshed can also include nonvolatile memory.

Memory controller 720 represents one or more memory controller circuits or devices for system 700. Memory controller 720 represents control logic that generates memory access commands in response to the execution of operations by processor 710. Memory controller 720 accesses one or more memory devices 740. Memory devices 740 can be DRAM devices in accordance with any referred to above. In one example, memory devices 740 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 720 manages a separate memory channel, although system 700 can be configured to have multiple channels managed by a single controller, or to have multiple controllers on a single channel. In one example, memory controller 720 is part of host processor 710, such as logic implemented on the same die or implemented in the same package space as the processor.

Memory controller 720 includes I/O interface logic 722 to couple to a memory bus, such as a memory channel as referred to above. I/O interface logic 722 (as well as I/O interface logic 742 of memory device 740) can include pins, pads, connectors, signal lines, traces, or wires, or other hardware to connect the devices, or a combination of these. I/O interface logic 722 can include a hardware interface. As illustrated, I/O interface logic 722 includes at least drivers/transceivers for signal lines. Commonly, wires within an integrated circuit interface couple with a pad, pin, or connector to interface signal lines or traces or other wires between devices. I/O interface logic 722 can include drivers, receivers, transceivers, or termination, or other circuitry or combinations of circuitry to exchange signals on the signal lines between the devices. The exchange of signals includes at least one of transmit or receive. While shown as coupling I/O 722 from memory controller 720 to I/O 742 of memory device 740, it will be understood that in an implementation of system 700 where groups of memory devices 740 are accessed in parallel, multiple memory devices can include I/O interfaces to the same interface of memory controller 720. In an implementation of system 700 including one or more memory modules 770, I/O 742 can include interface hardware of the memory module in addition to interface hardware on the memory device itself. Other memory controllers 720 will include separate interfaces to other memory devices 740.

The bus between memory controller 720 and memory devices 740 can be implemented as multiple signal lines coupling memory controller 720 to memory devices 740. The bus may typically include at least clock (CLK) 732, command/address (CMD) 734, and write data (DQ) and read data (DQ) 736, and zero or more other signal lines 738. In one example, a bus or connection between memory controller 720 and memory can be referred to as a memory bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 700 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 720 and memory devices 740. An example of a serial bus technology is 8B10B encoding and transmission of high-speed data with embedded clock over a single differential pair of signals in each direction. In one example, CMD 734 represents signal lines shared in parallel with multiple memory devices. In one example, multiple memory devices share encoding command signal lines of CMD 734, and each has a separate chip select (CS_n) signal line to select individual memory devices.

It will be understood that in the example of system 700, the bus between memory controller 720 and memory devices 740 includes a subsidiary command bus CMD 734 and a subsidiary bus to carry the write and read data, DQ 736. In one example, the data bus can include bidirectional lines for read data and for write/command data. In another example, the subsidiary bus DQ 736 can include unidirectional write signal lines for write and data from the host to memory, and can include unidirectional lines for read data from the memory to the host. In accordance with the chosen memory technology and system design, other signals 738 may accompany a bus or sub bus, such as strobe lines DQS. Based on design of system 700, or implementation if a design supports multiple implementations, the data bus can have more or less bandwidth per memory device 740. For example, the data bus can support memory devices that have either a x32 interface, a x16 interface, a x8 interface, or other interface. The convention “xW,” where W is an integer that refers to an interface size or width of the interface of memory device 740, which represents a number of signal lines to exchange data with memory controller 720. The interface size of the memory devices is a controlling factor on how many memory devices can be used concurrently per channel in system 700 or coupled in parallel to the same signal lines. In one example, high bandwidth memory devices, wide interface devices, or stacked memory configurations, or combinations, can enable wider interfaces, such as a x128 interface, a x256 interface, a x512 interface, a x1024 interface, or other data bus interface width.

In one example, memory devices 740 and memory controller 720 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length 8 (BL8), and each memory device 740 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 740 represent memory resources for system 700. In one example, each memory device 740 is a separate memory die. In one example, each memory device 740 can interface with multiple (e.g., 2) channels per device or die. Each memory device 740 includes I/O interface logic 742, which has a bandwidth determined by the implementation of the device (e.g., x16 or x8 or some other interface bandwidth). I/O interface logic 742 enables the memory devices to interface with memory controller 720. I/O interface logic 742 can include a hardware interface, and can be in accordance with I/O 722 of memory controller, but at the memory device end. In one example, multiple memory devices 740 are connected in parallel to the same command and data buses. In another example, multiple memory devices 740 are connected in parallel to the same command bus, and are connected to different data buses. For example, system 700 can be configured with multiple memory devices 740 coupled in parallel, with each memory device responding to a command, and accessing memory resources 760 internal to each. For a Write operation, an individual memory device 740 can write a portion of the overall data word, and for a Read operation, an individual memory device 740 can fetch a portion of the overall data word. As non-limiting examples, a specific memory device can provide or receive, respectively, 8 bits of a 128-bit data word for a Read or Write transaction, or 8 bits or 16 bits (depending for a x8 or a x16 device) of a 256-bit data word. The remaining bits of the word will be provided or received by other memory devices in parallel.

In one example, memory devices 740 are disposed directly on a motherboard or host system platform (e.g., a PCB (printed circuit board) on which processor 710 is disposed) of a computing device. In one example, memory devices 740 can be organized into memory modules 770. In one example, memory modules 770 represent dual inline memory modules (DIMMs). In one example, memory modules 770 represent other organization of multiple memory devices to share at least a portion of access or control circuitry, which can be a separate circuit, a separate device, or a separate board from the host system platform. Memory modules 770 can include multiple memory devices 740, and the memory modules can include support for multiple separate channels to the included memory devices disposed on them. In another example, memory devices 740 may be incorporated into the same package as memory controller 720, such as by techniques such as multi-chip-module (MCM), package-on-package, through-silicon via (TSV), or other techniques or combinations. Similarly, in one example, multiple memory devices 740 may be incorporated into memory modules 770, which themselves may be incorporated into the same package as memory controller 720. It will be appreciated that for these and other implementations, memory controller 720 may be part of host processor 710.

Memory devices 740 each include memory resources 760. Memory resources 760 represent individual arrays of memory locations or storage locations for data. Typically memory resources 760 are managed as rows of data, accessed via wordline (rows) and bitline (individual bits within a row) control. Memory resources 760 can be organized as separate channels, ranks, and banks of memory. Channels may refer to independent control paths to storage locations within memory devices 740. Ranks may refer to common locations across multiple memory devices (e.g., same row addresses within different devices). Banks may refer to arrays of memory locations within a memory device 740. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 740 include one or more registers 744. Register 744 represents one or more storage devices or storage locations that provide configuration or settings for the operation of the memory device. In one example, register 744 can provide a storage location for memory device 740 to store data for access by memory controller 720 as part of a control or management operation. In one example, register 744 includes one or more Mode Registers. In one example, register 744 includes one or more multipurpose registers. The configuration of locations within register 744 can configure memory device 740 to operate in different “modes,” where command information can trigger different operations within memory device 740 based on the mode. Additionally or in the alternative, different modes can also trigger different operation from address information or other signal lines depending on the mode. Settings of register 744 can indicate configuration for I/O settings (e.g., timing, termination or ODT (on-die termination) 746, driver configuration, or other I/O settings).

In one example, memory device 740 includes ODT 746 as part of the interface hardware associated with I/O 742. ODT 746 can be configured as mentioned above, and provide settings for impedance to be applied to the interface to specified signal lines. In one example, ODT 746 is applied to DQ signal lines. In one example, ODT 746 is applied to command signal lines. In one example, ODT 746 is applied to address signal lines. In one example, ODT 746 can be applied to any combination of the preceding. The ODT settings can be changed based on whether a memory device is a selected target of an access operation or a non-target device. ODT 746 settings can affect the timing and reflections of signaling on the terminated lines. Careful control over ODT 746 can enable higher-speed operation with improved matching of applied impedance and loading. ODT 746 can be applied to specific signal lines of I/O interface 742, 722, and is not necessarily applied to all signal lines.

Memory device 740 includes controller 750, which represents control logic within the memory device to control internal operations within the memory device. For example, controller 750 decodes commands sent by memory controller 720 and generates internal operations to execute or satisfy the commands. Controller 750 can be referred to as an internal controller, and is separate from memory controller 720 of the host. Controller 750 can determine what mode is selected based on register 744, and configure the internal execution of operations for access to memory resources 760 or other operations based on the selected mode. Controller 750 generates control signals to control the routing of bits within memory device 740 to provide a proper interface for the selected mode and direct a command to the proper memory locations or addresses. Controller 750 includes command logic 752, which can decode command encoding received on command and address signal lines. Thus, command logic 752 can be or include a command decoder. With command logic 752, memory device can identify commands and generate internal operations to execute requested commands.

Referring again to memory controller 720, memory controller 720 includes command (CMD) logic 724, which represents logic or circuitry to generate commands to send to memory devices 740. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 740, memory controller 720 can issue commands via I/O 722 to cause memory device 740 to execute the commands. In one example, controller 750 of memory device 740 receives and decodes command and address information received via I/O 742 from memory controller 720. Based on the received command and address information, controller 750 can control the timing of operations of the logic and circuitry within memory device 740 to execute the commands. Controller 750 is responsible for compliance with standards or specifications within memory device 740, such as timing and signaling requirements. Memory controller 720 can implement compliance with standards or specifications by access scheduling and control.

Memory controller 720 includes scheduler 730, which represents logic or circuitry to generate and order transactions to send to memory device 740. From one perspective, the primary function of memory controller 720 could be said to schedule memory access and other transactions to memory device 740. Such scheduling can include generating the transactions themselves to implement the requests for data by processor 710 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 720 typically includes logic such as scheduler 730 to allow selection and ordering of transactions to improve performance of system 700. Thus, memory controller 720 can select which of the outstanding transactions should be sent to memory device 740 in which order, which is typically achieved with logic much more complex that a simple first-in first-out algorithm. Memory controller 720 manages the transmission of the transactions to memory device 740, and manages the timing associated with the transaction. In one example, transactions have deterministic timing, which can be managed by memory controller 720 and used in determining how to schedule the transactions with scheduler 730.

In one example, memory controller 720 includes refresh (REF) logic 726. Refresh logic 726 can be used for memory resources that are volatile and need to be refreshed to retain a deterministic state. In one example, refresh logic 726 indicates a location for refresh, and a type of refresh to perform. Refresh logic 726 can trigger self-refresh within memory device 740, or execute external refreshes which can be referred to as auto refresh commands) by sending refresh commands, or a combination. In one example, system 700 supports all bank refreshes as well as per bank refreshes. All bank refreshes cause the refreshing of banks within all memory devices 740 coupled in parallel. Per bank refreshes cause the refreshing of a specified bank within a specified memory device 740. In one example, controller 750 within memory device 740 includes refresh logic 754 to apply refresh within memory device 740. In one example, refresh logic 754 generates internal operations to perform refresh in accordance with an external refresh received from memory controller 720. Refresh logic 754 can determine if a refresh is directed to memory device 740, and what memory resources 760 to refresh in response to the command.

In one example, memory device 740 represents a multi-device memory package, which includes redundancy logic 780. As a multi-device memory, memory resources 760 can include multiple individual memory dies stacked vertically or in one or more vertical stacks. Redundancy logic 780 represents logic within memory device 740 to provide redundancy for memory device 740 to achieve error recovery for memory resources that store an entire cacheline of data. Redundancy logic 780 includes one or more memory resources that are spares or that provide parity services, or both. In one example, redundancy logic 780 includes additional logic, whether circuitry or control logic or both, to implement calculations that enable data recovery.

In one example, memory controller 720 includes redundancy logic 728, which represents logic within memory controller 720 to manage memory device 740 in accordance with additional redundancy resources within the memory. In one example, redundancy logic 728 represents control logic of scheduler 730, and memory controller 720 issues commands and controls the timing of commands and access in accordance with the redundancy available at memory device 740. In one example, redundancy logic 728 represents ECC logic at memory controller 720, which can computer system-level error recovery based on the recovery capabilities of one or more memory devices 740.

In one example, memory controllers 720 manage multiple memory devices 740 that are multi-device memories with redundancy in accordance with any example herein. In one example, memory controllers 720 can implement error recovery of memory devices 740 beyond a single channel. For example, each data block (where a data block refers to a chunk of data larger than a cacheline) can be stored on a separate and independent channel. In one example, each data block can be stored on multiple different HBM devices. In one example, memory controllers 720 support multi-channel lock-step among different memory devices 740. For example, assume one HBM includes 8 independent channels. In such an implementation, system 700 can include two memory controllers 720 for the 8 channels, each controlling 4 channels. A master memory controller or other logic at the host or on processor 710 can coordinate the operation of the two separate memory controllers for the 8 channels. Thus, system 700 can include logic to implement redundancy across channels, across HBM memory devices 740, or a combination, where the redundancy is coordinated among multiple separate or independent memory controllers 720. Thus, the error recovery can be coordinated over data managed by separate memory controllers 720.

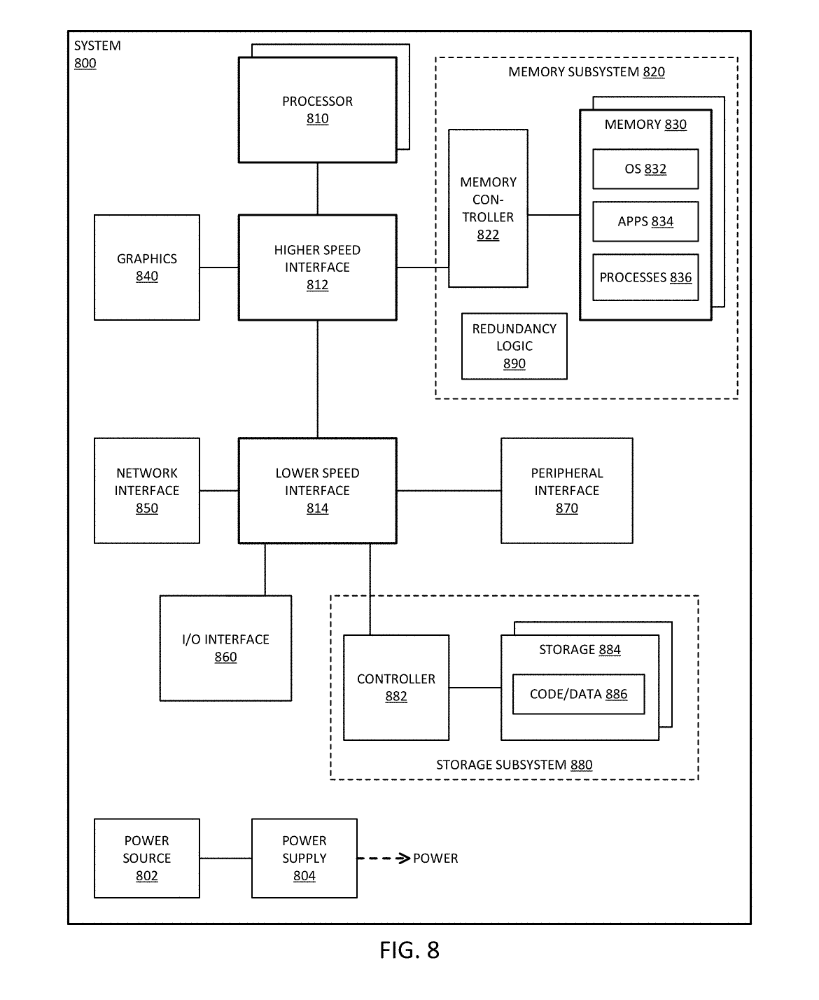

FIG. 8 is a block diagram of an example of a computing system in which a multi-device memory with redundancy logic can be implemented. System 800 represents a computing device in accordance with any example herein, and can be a laptop computer, a desktop computer, a tablet computer, a server, a gaming or entertainment control system, a scanner, copier, printer, routing or switching device, embedded computing device, a smartphone, a wearable device, an internet-of-things device or other electronic device.

System 800 includes processor 810, which provides processing, operation management, and execution of instructions for system 800. Processor 810 can include any type of microprocessor, central processing unit (CPU), graphics processing unit (GPU), processing core, or other processing hardware to provide processing for system 800, or a combination of processors. Processor 810 controls the overall operation of system 800, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 800 includes interface 812 coupled to processor 810, which can represent a higher speed interface or a high throughput interface for system components that needs higher bandwidth connections, such as memory subsystem 820 or graphics interface components 840. Interface 812 represents an interface circuit, which can be a standalone component or integrated onto a processor die. Where present, graphics interface 840 interfaces to graphics components for providing a visual display to a user of system 800. In one example, graphics interface 840 can drive a high definition (HD) display that provides an output to a user. High definition can refer to a display having a pixel density of approximately 100 PPI (pixels per inch) or greater, and can include formats such as full HD (e.g., 1080p), retina displays, 4K (ultra high definition or UHD), or others. In one example, the display can include a touchscreen display. In one example, graphics interface 840 generates a display based on data stored in memory 830 or based on operations executed by processor 810 or both. In one example, graphics interface 840 generates a display based on data stored in memory 830 or based on operations executed by processor 810 or both.

Memory subsystem 820 represents the main memory of system 800, and provides storage for code to be executed by processor 810, or data values to be used in executing a routine. Memory subsystem 820 can include one or more memory devices 830 such as read-only memory (ROM), flash memory, one or more varieties of random access memory (RAM) such as DRAM, or other memory devices, or a combination of such devices. Memory 830 stores and hosts, among other things, operating system (OS) 832 to provide a software platform for execution of instructions in system 800. Additionally, applications 834 can execute on the software platform of OS 832 from memory 830. Applications 834 represent programs that have their own operational logic to perform execution of one or more functions. Processes 836 represent agents or routines that provide auxiliary functions to OS 832 or one or more applications 834 or a combination. OS 832, applications 834, and processes 836 provide software logic to provide functions for system 800. In one example, memory subsystem 820 includes memory controller 822, which is a memory controller to generate and issue commands to memory 830. It will be understood that memory controller 822 could be a physical part of processor 810 or a physical part of interface 812. For example, memory controller 822 can be an integrated memory controller, integrated onto a circuit with processor 810.

While not specifically illustrated, it will be understood that system 800 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus.

In one example, system 800 includes interface 814, which can be coupled to interface 812. Interface 814 can be a lower speed interface than interface 812. In one example, interface 814 represents an interface circuit, which can include standalone components and integrated circuitry. In one example, multiple user interface components or peripheral components, or both, couple to interface 814. Network interface 850 provides system 800 the ability to communicate with remote devices (e.g., servers or other computing devices) over one or more networks. Network interface 850 can include an Ethernet adapter, wireless interconnection components, cellular network interconnection components, USB (universal serial bus), or other wired or wireless standards-based or proprietary interfaces. Network interface 850 can exchange data with a remote device, which can include sending data stored in memory or receiving data to be stored in memory.

In one example, system 800 includes one or more input/output (I/O) interface(s) 860. I/O interface 860 can include one or more interface components through which a user interacts with system 800 (e.g., audio, alphanumeric, tactile/touch, or other interfacing). Peripheral interface 870 can include any hardware interface not specifically mentioned above. Peripherals refer generally to devices that connect dependently to system 800. A dependent connection is one where system 800 provides the software platform or hardware platform or both on which operation executes, and with which a user interacts.

In one example, system 800 includes storage subsystem 880 to store data in a nonvolatile manner. In one example, in certain system implementations, at least certain components of storage 880 can overlap with components of memory subsystem 820. Storage subsystem 880 includes storage device(s) 884, which can be or include any conventional medium for storing large amounts of data in a nonvolatile manner, such as one or more magnetic, solid state, or optical based disks, or a combination. Storage 884 holds code or instructions and data 886 in a persistent state (i.e., the value is retained despite interruption of power to system 800). Storage 884 can be generically considered to be a “memory,” although memory 830 is typically the executing or operating memory to provide instructions to processor 810. Whereas storage 884 is nonvolatile, memory 830 can include volatile memory (i.e., the value or state of the data is indeterminate if power is interrupted to system 800). In one example, storage subsystem 880 includes controller 882 to interface with storage 884. In one example controller 882 is a physical part of interface 814 or processor 810, or can include circuits or logic in both processor 810 and interface 814.

Power source 802 provides power to the components of system 800. More specifically, power source 802 typically interfaces to one or multiple power supplies 804 in system 802 to provide power to the components of system 800. In one example, power supply 804 includes an AC to DC (alternating current to direct current) adapter to plug into a wall outlet. Such AC power can be renewable energy (e.g., solar power) power source 802. In one example, power source 802 includes a DC power source, such as an external AC to DC converter. In one example, power source 802 or power supply 804 includes wireless charging hardware to charge via proximity to a charging field. In one example, power source 802 can include an internal battery or fuel cell source.

In one example, memory subsystem 1020 includes redundancy logic 1090, which represents redundancy capability in a multichip memory in accordance with any example herein. The redundancy can enable extra data stored within the multichip or multi-device or multi-die memory 1030. The redundancy enables extra levels of data protection, which can provide higher reliability for high density memory devices.

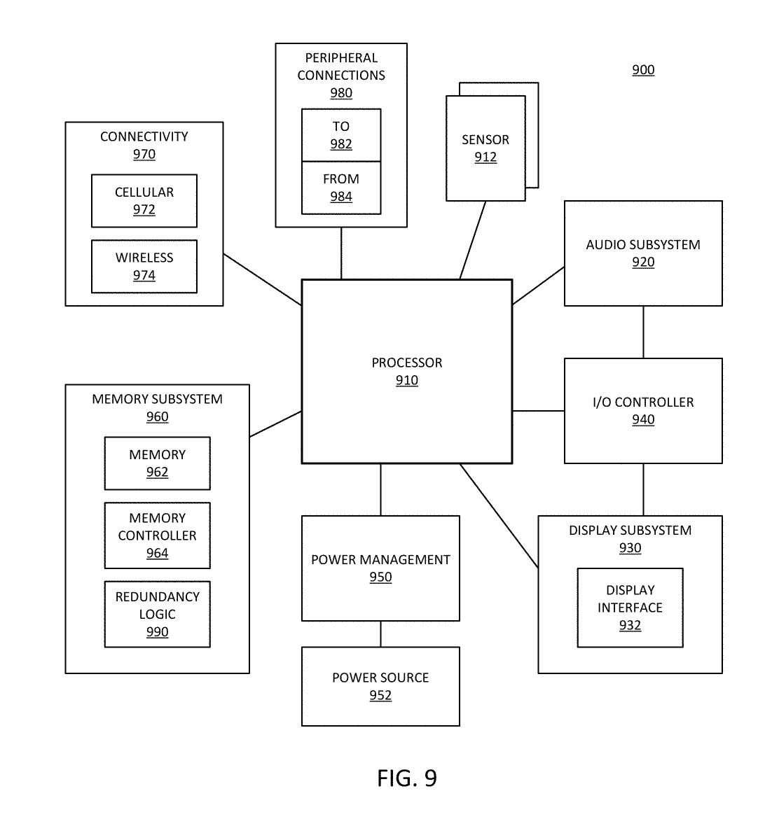

FIG. 9 is a block diagram of an example of a mobile device in which a multi-device memory with redundancy logic can be implemented. Device 900 represents a mobile computing device, such as a computing tablet, a mobile phone or smartphone, a wireless-enabled e-reader, wearable computing device, an internet-of-things device or other mobile device, or an embedded computing device. It will be understood that certain of the components are shown generally, and not all components of such a device are shown in device 900.

Device 900 includes processor 910, which performs the primary processing operations of device 900. Processor 910 can include one or more physical devices, such as microprocessors, application processors, microcontrollers, programmable logic devices, or other processing means. The processing operations performed by processor 910 include the execution of an operating platform or operating system on which applications and device functions are executed. The processing operations include operations related to I/O (input/output) with a human user or with other devices, operations related to power management, operations related to connecting device 900 to another device, or a combination. The processing operations can also include operations related to audio I/O, display I/O, or other interfacing, or a combination. Processor 910 can execute data stored in memory. Processor 910 can write or edit data stored in memory.

In one example, system 900 includes one or more sensors 912. Sensors 912 represent embedded sensors or interfaces to external sensors, or a combination. Sensors 912 enable system 900 to monitor or detect one or more conditions of an environment or a device in which system 900 is implemented. Sensors 912 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 912 can also include sensors for biometric systems such as fingerprint recognition systems, face detection or recognition systems, or other systems that detect or recognize user features. Sensors 912 should be understood broadly, and not limiting on the many different types of sensors that could be implemented with system 900. In one example, one or more sensors 912 couples to processor 910 via a frontend circuit integrated with processor 910. In one example, one or more sensors 912 couples to processor 910 via another component of system 900.

In one example, device 900 includes audio subsystem 920, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into device 900, or connected to device 900. In one example, a user interacts with device 900 by providing audio commands that are received and processed by processor 910.

Display subsystem 930 represents hardware (e.g., display devices) and software components (e.g., drivers) that provide a visual display for presentation to a user. In one example, the display includes tactile components or touchscreen elements for a user to interact with the computing device. Display subsystem 930 includes display interface 932, which includes the particular screen or hardware device used to provide a display to a user. In one example, display interface 932 includes logic separate from processor 910 (such as a graphics processor) to perform at least some processing related to the display. In one example, display subsystem 930 includes a touchscreen device that provides both output and input to a user. In one example, display subsystem 930 includes a high definition (HD) display that provides an output to a user. High definition can refer to a display having a pixel density of approximately 100 PPI (pixels per inch) or greater, and can include formats such as full HD (e.g., 1080p), retina displays, 4K (ultra high definition or UHD), or others. In one example, display subsystem includes a touchscreen display. In one example, display subsystem 930 generates display information based on data stored in memory or based on operations executed by processor 910 or both.

I/O controller 940 represents hardware devices and software components related to interaction with a user. I/O controller 940 can operate to manage hardware that is part of audio subsystem 920, or display subsystem 930, or both. Additionally, I/O controller 940 illustrates a connection point for additional devices that connect to device 900 through which a user might interact with the system. For example, devices that can be attached to device 900 might include microphone devices, speaker or stereo systems, video systems or other display device, keyboard or keypad devices, or other I/O devices for use with specific applications such as card readers or other devices.

As mentioned above, I/O controller 940 can interact with audio subsystem 920 or display subsystem 930 or both. For example, input through a microphone or other audio device can provide input or commands for one or more applications or functions of device 900. Additionally, audio output can be provided instead of or in addition to display output. In another example, if display subsystem includes a touchscreen, the display device also acts as an input device, which can be at least partially managed by I/O controller 940. There can also be additional buttons or switches on device 900 to provide I/O functions managed by I/O controller 940.

In one example, I/O controller 940 manages devices such as accelerometers, cameras, light sensors or other environmental sensors, gyroscopes, global positioning system (GPS), or other hardware that can be included in device 900, or sensors 912. The input can be part of direct user interaction, as well as providing environmental input to the system to influence its operations (such as filtering for noise, adjusting displays for brightness detection, applying a flash for a camera, or other features).

In one example, device 900 includes power management 950 that manages battery power usage, charging of the battery, and features related to power saving operation. Power management 950 manages power from power source 952, which provides power to the components of system 900. In one example, power source 952 includes an AC to DC (alternating current to direct current) adapter to plug into a wall outlet. Such AC power can be renewable energy (e.g., solar power, motion based power). In one example, power source 952 includes only DC power, which can be provided by a DC power source, such as an external AC to DC converter. In one example, power source 952 includes wireless charging hardware to charge via proximity to a charging field. In one example, power source 952 can include an internal battery or fuel cell source.

Memory subsystem 960 includes memory device(s) 962 for storing information in device 900. Memory subsystem 960 can include nonvolatile (state does not change if power to the memory device is interrupted) or volatile (state is indeterminate if power to the memory device is interrupted) memory devices, or a combination. Memory 960 can store application data, user data, music, photos, documents, or other data, as well as system data (whether long-term or temporary) related to the execution of the applications and functions of system 900. In one example, memory subsystem 960 includes memory controller 964 (which could also be considered part of the control of system 900, and could potentially be considered part of processor 910). Memory controller 964 includes a scheduler to generate and issue commands to control access to memory device 962.

Connectivity 970 includes hardware devices (e.g., wireless or wired connectors and communication hardware, or a combination of wired and wireless hardware) and software components (e.g., drivers, protocol stacks) to enable device 900 to communicate with external devices. The external device could be separate devices, such as other computing devices, wireless access points or base stations, as well as peripherals such as headsets, printers, or other devices. In one example, system 900 exchanges data with an external device for storage in memory or for display on a display device. The exchanged data can include data to be stored in memory, or data already stored in memory, to read, write, or edit data.

Connectivity 970 can include multiple different types of connectivity. To generalize, device 900 is illustrated with cellular connectivity 972 and wireless connectivity 974. Cellular connectivity 972 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 974 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 980 include hardware interfaces and connectors, as well as software components (e.g., drivers, protocol stacks) to make peripheral connections. It will be understood that device 900 could both be a peripheral device (“to” 982) to other computing devices, as well as have peripheral devices (“from” 984) connected to it. Device 900 commonly has a “docking” connector to connect to other computing devices for purposes such as managing (e.g., downloading, uploading, changing, synchronizing) content on device 900. Additionally, a docking connector can allow device 900 to connect to certain peripherals that allow device 900 to control content output, for example, to audiovisual or other systems.

In addition to a proprietary docking connector or other proprietary connection hardware, device 900 can make peripheral connections 980 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

In one example, memory subsystem 1160 includes redundancy logic 1190, which represents redundancy capability in a multichip memory in accordance with any example herein. The redundancy can enable extra data stored within the multichip or multi-device or multi-die memory 1162. The redundancy enables extra levels of data protection, which can provide higher reliability for high density memory devices.

In one example, a memory controller includes: a hardware data interface to couple to a multi-device memory package, wherein the multi-device memory package is to include multiple memory devices daisy-chained together, the memory devices to include exclusive OR (XOR) circuitry local to the memory device, and wherein a memory device at an end of the daisy chain farthest from the memory controller is to store parity data; and a scheduler to control sending of access commands to the memory devices based on write command timing that accounts for a read-modify-write for a write command to one of the memory devices, and for read-modify write of the parity data.

In one example, the scheduler is to schedule the sending of a write command as two sub-commands, with a first sub-command to write data to an addressed memory device, and a second sub-command to write parity data. In one example, the scheduler is to schedule the sending of a single write command to trigger the multi-device memory package to write data to an addressed memory device, and automatically write parity data in response to the write command. In one example, the scheduler is to control sending of access commands to the memory devices based on read command timing that accounts for parity checking and data reconstruction.

In one example, a multichip memory device includes: multiple memory dies, where a memory die physically farthest from an associated memory controller along a signal path is to store parity data; and exclusive OR (XOR) logic to compute parity for the multiple memory dies for a write command; wherein in response to a write command, a memory die is to write the data, and the memory die farthest from the memory controller is to store parity data based on the write command.

In one example, the multiple memory dies comprise memory dies in a vertical stack. In one example, the vertical stack is to couple the memory dies with through-silicon-via connections. In one example, the multiple memory dies comprise four memory dies with three data dies and one parity die. In one example, the multiple memory dies comprise eight memory dies with multiple parity dies and multiple data dies. In one example, the multiple memory dies are to receive a write access as two sub-commands, with one sub-command to write the data, and a second sub-command to write the parity data. In one example, the multiple memory dies are to receive a write access as a single command, and in response to the command to write the data, and also to write the parity data. In one example, the multiple memory dies are to write data as a read-modify-write operation. In one example, the memory die farthest from the memory controller is to write the parity data as a read-modify-write operation. In one example, the XOR logic comprises XOR logic local to every memory die.

In one example, a system includes: a memory controller including a scheduler to control sending of access commands based on write command timing that accounts for a read-modify-write to write data in response to a write command, and for a read-modify write of parity data in response to the write command; and a multichip memory device coupled to the memory controller, including multiple memory dies coupled in a daisy chain; and exclusive OR (XOR) logic to compute parity for the multiple memory dies for a write command; wherein in response to a write command, a memory die is to write the data, and the memory die farthest from the memory controller is to store parity data based on the write command.

In one example, a memory controller includes: a hardware data interface to couple to a multi-device memory package, wherein the multi-device memory package is to include multiple memory devices to store data and parity data to recover the data; and a scheduler to control sending of access commands to the memory devices based on write command timing that accounts for a read-modify-write for a write command to one of the memory devices, and for read-modify write of the parity data.

In one example, the multi-device memory package is to include multiple memory devices daisy-chained together, and wherein a memory device at an end of the daisy chain farthest from the memory controller is to store parity data. In one example, the memory devices to include exclusive OR (XOR) circuitry local to the memory device. In one example, the scheduler is to schedule the sending of a write command as two sub-commands, with a first sub-command to write data to an addressed memory device, and a second sub-command to write parity data. In one example, the scheduler is to schedule the sending of a single write command to trigger the multi-device memory package to write data to an addressed memory device, and automatically write parity data in response to the write command. In one example, the scheduler is to control sending of access commands to the memory devices based on read command timing that accounts for parity checking and data reconstruction.

In one example, a multichip memory device includes: multiple memory dies coupled in a daisy chain, where a memory die farthest from an associated memory controller is to store parity data; wherein in response to a write command, a memory die is to write the data, and the memory die farthest from the memory controller is to store parity data based on the write command.

In one example, exclusive OR (XOR) logic to compute parity for the multiple memory dies for a write command. In one example, the XOR logic comprises XOR logic local to every memory die. In one example, the multiple memory dies comprise memory dies in a vertical stack. In one example, the vertical stack is to couple the memory dies with through-silicon-via connections. In one example, the multiple memory dies comprise four memory dies with three data dies and one parity die. In one example, the multiple memory dies comprise eight memory dies with multiple parity dies and multiple data dies. In one example, the multiple memory dies are to receive a write access as two sub-commands, with one sub-command to write the data, and a second sub-command to write the parity data. In one example, the multiple memory dies are to receive a write access as a single command, and in response to the command to write the data, and also to write the parity data. In one example, the multiple memory dies are to write data as a read-modify-write operation. In one example, the memory die farthest from the memory controller is to write the parity data as a read-modify-write operation.

In one example, a system includes: a memory controller including a scheduler to control sending of access commands based on write command timing that accounts for a read-modify-write to write data in response to a write command, and for a read-modify write of parity data in response to the write command; and a multichip memory device coupled to the memory controller, including multiple memory dies coupled in a daisy chain to store data and parity data to recover the data.

In one example, a system includes: a memory controller including a scheduler to control sending of access commands based on write command timing that accounts for a read-modify-write to write data in response to a write command, and for a read-modify write of parity data in response to the write command; and a multichip memory device coupled to the memory controller, including multiple memory dies, including at least one memory die to store data and at least one die to store parity data to recover the data.

In one example, the multichip memory device is to include multiple memory devices daisy-chained together, and wherein a memory device at an end of the daisy chain farthest from the memory controller is to store parity data. In one example, the memory devices to include exclusive OR (XOR) circuitry local to the memory device. In one example, the scheduler is to schedule the sending of a write command as two sub-commands, with a first sub-command to write data to an addressed memory device, and a second sub-command to write parity data. In one example, the scheduler is to schedule the sending of a single write command to trigger the multi-device memory package to write data to an addressed memory device, and automatically write parity data in response to the write command. In one example, the scheduler is to control sending of access commands to the memory devices based on read command timing that accounts for parity checking and data reconstruction. In one example, the multiple memory dies comprise memory dies in a vertical stack. In one example, further comprising one or more of: at least one processor communicatively coupled to the host controller; a display communicatively coupled to at least one processor; a network interface communicatively coupled to at least one processor; or a battery to power the system.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A memory controller, comprising:
a hardware data interface to couple to a multi-device memory package, wherein the multi-device memory package is to include multiple memory devices to store data and parity data to recover the data; and
a scheduler to control sending of access commands to the memory devices based on write command timing that accounts for a read-modify-write for a write command to one of the memory devices, and for read-modify write of the parity data.

2. The memory controller of claim 1, wherein the memory devices to include exclusive OR (XOR) circuitry local to the memory device.

3. The memory controller of claim 1, wherein the scheduler is to schedule the sending of a write command as two sub-commands, with a first sub-command to write data to an addressed memory device, and a second sub-command to write parity data.

4. The memory controller of claim 1, wherein the scheduler is to schedule the sending of a single write command to trigger the multi-device memory package to write data to an addressed memory device, and automatically write parity data in response to the write command.

5. The memory controller of claim 1, wherein the scheduler is to control sending of access commands to the memory devices based on read command timing that accounts for parity checking and data reconstruction.

6. A multichip memory device, comprising:
multiple memory dies, where a memory die physically farthest from an associated memory controller along a signal path is to store parity data; and
exclusive OR (XOR) logic to compute parity for the multiple memory dies for a write command;
wherein in response to a write command, a memory die is to write the data, and the memory die farthest from the memory controller is to store parity data based on the write command.

7. The multichip memory device of claim 6, wherein the multiple memory dies comprise memory dies in a vertical stack.

8. The multichip memory device of claim 7, wherein the vertical stack is to couple the memory dies with through-silicon-via connections.

9. The multichip memory device of claim 6, wherein the multiple memory dies comprise four memory dies with three data dies and one parity die.

10. The multichip memory device of claim 6, wherein the multiple memory dies comprise eight memory dies with multiple parity dies and multiple data dies.

11. The multichip memory device of claim 6, wherein the multiple memory dies are to receive a write access as two sub-commands, with one sub-command to write the data, and a second sub-command to write the parity data.

12. The multichip memory device of claim 6, wherein the multiple memory dies are to receive a write access as a single command, and in response to the command to write the data, and also to write the parity data.

13. The multichip memory device of claim 6, wherein the multiple memory dies are to write data as a read-modify-write operation.

14. The multichip memory device of claim 6, wherein the memory die farthest from the memory controller is to write the parity data as a read-modify-write operation.

15. The multichip memory device of claim 6, wherein the XOR logic comprises XOR logic local to every memory die.

16. A system, comprising:
a memory controller including
a scheduler to control sending of access commands based on write command timing that accounts for a read-modify-write to write data in response to a write command, and for a read-modify write of parity data in response to the write command; and
a multichip memory device coupled to the memory controller, including
multiple memory dies, including at least one memory die to store data and at least one die to store parity data to recover the data.

17. The system of claim 16, wherein the multichip memory device is to include multiple memory devices daisy-chained together, and wherein a memory device at an end of the daisy chain farthest from the memory controller is to store parity data.

18. The system of claim 16, wherein the multichip memory device is to include multiple memory devices coupled together, with data devices having a dedicated connection to a parity device physically farther from the memory controller than the data devices.

19. The system of claim 16, wherein the memory devices to include exclusive OR (XOR) circuitry local to the memory device, wherein the read-modify-write is to include a read of the data, modification with the XOR circuitry, and a write of the data.

20. The system of claim 16, wherein the scheduler is to schedule the sending of a write command as two sub-commands, with a first sub-command to write data to an addressed memory device, and a second sub-command to write parity data.

21. The system of claim 16, wherein the scheduler is to schedule the sending of a single write command to trigger the multi-device memory package to write data to an addressed memory device, and automatically write parity data in response to the write command.

22. The system of claim 16, wherein the scheduler is to control sending of access commands to the memory devices based on read command timing that accounts for parity checking and data reconstruction.

23. The system of claim 16, wherein the multiple memory dies comprise memory dies in a vertical stack.

24. The system of claim 16, further comprising one or more of:
at least one processor communicatively coupled to the host controller;
a display communicatively coupled to at least one processor;
a network interface communicatively coupled to at least one processor; or
a battery to power the system.
